(19) United States
(12) Patent Application Publication
(10) Pub. No.: US 2011/0003102 A1
(43) Pub. Date: Jan. 6, 2011

(54) METHOD FOR MAKING HOUSING AND HOUSING THEREOF

(75) Inventors: QIN-ZHENG HOU, Shenzhen City (CN); YAN-MIN WANG, Shenzhen City (CN); GANG HUANG, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/702,377

(22) Filed: Feb. 9, 2010

(30) Foreign Application Priority Data
Jul. 6, 2009 (CN) 200910304052.7

(51) Int. Cl. H05K 5/02; B32B 15/08; B32B 27/06; B32B 1/00; B29C 70/78; B29B 15/10

(52) U.S. Cl. 428/35.9; 264/135; 264/132

(57) ABSTRACT

A method for making a housing comprises providing a transparent film; forming a metallic coating on the film; forming a protective coating on the metallic coating; and molding a substrate on the protective coating. A housing made by the method is also described there.

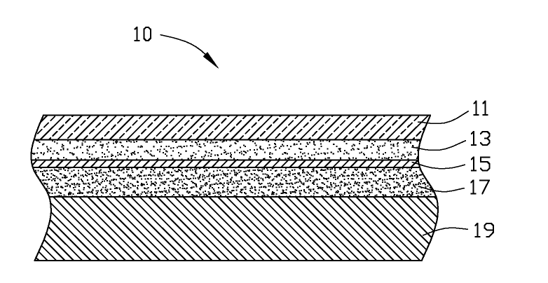

### BACKGROUND

1. Technical Field

The present disclosure relates to methods for making housings, especially to a method for making housing having a metallic appearance, and a housing thereof.

2. Description of Related Art

In-Mold Label (IML) process is now a typical method used to produce housings of electronic devices. Housings formed by IML processes commonly include a transparent plastic film and optionally a pattern printed on the film, and a plastic substrate molded on the film and pattern. The pattern will not be abraded because it is disposed between the film and the substrate, and so the appearance of the housing can be maintained. However, housings made in this way will often not have a metallic appearance, which may be considered more attractive.

Therefore, there is room for improvement within the art.

### BRIEF DESCRIPTION OF THE FIGURE

Many aspects of the housing can be better understood with reference to the following FIGURE. The components in the figure are not necessarily drawn to scale, the emphasis instead being placed upon clearly illustrating the principles of the housing.

The FIGURE is a cross-sectional view of an exemplary embodiment of a housing.

### DETAILED DESCRIPTION

In an exemplary embodiment, a method for making a housing may comprise providing a transparent film; forming a metallic coating on the film; forming a protective coating on the metallic coating; and molding a substrate on the protective coating.

Referring to the FIGURE, a transparent film 11 is provided. The film 11 may be made of plastic. The plastic can be selected from a group consisting of polypropylene (PP), polyamide (PA), polycarbonate (PC), polymethyl methacrylate (PMMA), and polyethylene terephthalate (PET). The film 11 has a thickness of about 0.125-0.175 mm.

An optional decorative coating 13 may be formed on one surface of the film 11. The decorative coating 13 may be a transparent or translucent ink coating formed by printing. The decorative coating 13 can define a decorative pattern. The thickness of the decorative coating 13 may be about 3.5-4.5 μm.

A metallic coating 15 is applied on the exposed surface of the decorative coating 13. The metallic coating 15 may be formed by vacuum evaporation deposition or sputtering. The metallic coating 15 can be translucent or opaque, and has a metallic appearance. The material used for the metallic coating 15 can be indium, tin, indium-tin alloy, aluminum, titanium, titanium carbide, stainless steel or aluminum-silicon alloys. The metallic coating 15 can be made nonconductive by choosing from the above-mentioned materials and/or by controlling the thickness of the metallic coating 15 to be within a range of about 1-2 μm.

A protective coating 17 is applied on the exposed surface of the metallic coating 15. The protective coating 17 may be a transparent ultraviolet (UV) curing ink coating formed by printing. The UV ink can be repeatedly printed, forming 7-8 layers for example, to increase the thickness and the protective nature of the protective coating 17. Each layer of the printed UV ink coating may have a thickness of about 8-10 μm.

The coatings 11-17 are then applied to the interior of a mold and the substrate 19 is molded onto the protective coating 17 to form the housing. The material of molding the substrate 19 can be selected from a group consisting of polyethylene (PE), polycarbonate (PC), polyamide (PA), acrylonitrile-butadiene-styrene (ABS), polymethyl methacrylate (PMMA), and polyethylene terephthalate (PET).

Referring to the FIGURE, a housing 10 made by the above mentioned method includes a film 11, and a decorative coating 13, a metallic coating 15, a protective coating 17, a substrate 19 formed on the film 11 in that order. The decorative coating 13 is a transparent or translucent ink coating and defines a pattern, which can give the housing 10 an attractive appearance. The metallic coating 15 has a metallic appearance, which makes the housing 10 present a metallic appearance. The protective coating 17 is a transparent UV curing ink coating formed on the metallic coating 15. The substrate 19 is a plastic coating molded on the protective coating 17.

The exemplary method for making the housing 10 forms a metallic coating 15 by using a IML process to give the housing 10 an attractive metallic appearance. The metallic coating 15 would not be abraded for it is disposed between the film 11 and the substrate 19, with which the metallic appearance of the housing 10 would maintain permanently.

It should be understood, however, that even though numerous characteristics and advantages of the present embodiments have been set forth in the foregoing description, together with details of functions of the embodiments, the disclosure is illustrative only, and changes may be made in detail within the principles of the disclosure to the full extent indicated by the broad general meaning of the terms in which the appended claims are expressed.

What is claimed is:

1. A method for making a housing, comprising:
providing a transparent film;
forming a metallic coating on the film;
forming a protective coating on the metallic coating; and
molding a substrate on the protective coating.

2. The method as claimed in claim 1, wherein the metallic coating is formed by vacuum evaporation deposition or sputtering.

3. The method as claimed in claim 2, wherein the metallic coating contains indium, tin, indium-tin alloy, aluminum, titanium, titanium carbide, stainless steel or aluminum-silicon alloys.

4. The method as claimed in claim 3, wherein the metallic coating has a thickness of about 1-2 μm.

5. The method as claimed in claim 1, wherein the protective coating is a transparent ink coating formed by printing.

6. The method as claimed in claim 5, wherein the ink is ultraviolet curing ink.

7. The method as claimed in claim 1, further comprising printing a decorative coating on the film before forming the metallic coating.

8. The method as claimed in claim 7, wherein the metallic coating is formed on the decorative coating.

9. The method as claimed in claim 7, wherein the decorative coating is a transparent or translucent ink coating having a thickness of about 3.5-4.5 μm.

10. The method as claimed in claim 1, wherein the film is made of plastic selected from a group consisting of polypropylene, polyamide, polycarbonate, polymethyl methacrylate, and polyethylene terephthalate.

11. The method as claimed in claim 1, wherein the substrate is made of plastic selected from a group consisting of polyethylene, polycarbonate, polyamide, acrylonitrile-butadiene-styrene, polymethyl methacrylate, and polyethylene terephthalate.

12. A housing, comprising:
a film;
a metallic coating formed on the film;
a protective coating formed on the metallic coating; and
a substrate molded on the protective coating.

13. The housing as claimed in claim 12, wherein the metallic coating contains indium, tin, indium-tin alloy, aluminum, titanium, titanium carbide, stainless steel or aluminum-silicon alloys.

14. The housing as claimed in claim 13, wherein the metallic coating is formed by vacuum evaporation deposition or sputtering.

15. The housing as claimed in claim 14, wherein the metallic coating has a thickness of about 1-2 μm.

16. The housing as claimed in claim 12, wherein the protective coating is a transparent ink coating formed by printing.

17. The housing as claimed in claim 16, wherein the ink is ultraviolet curing ink.

18. The housing as claimed in claim 12, further comprising a decorative coating disposed between the film and the metallic coating.

19. The housing as claimed in claim 18, wherein the decorative coating is a transparent or translucent ink coating having a thickness of about 3.5-4.5 μm.
